(19) United States
(12) Patent Application Publication
(10) Pub. No.: US 2026/0068674 A1
(43) Pub. Date: Mar. 5, 2026

(54) AUTOMATED HEATSINK REMOVAL FROM PRINTED CIRCUIT BOARD ASSEMBLY

(71) Applicant: INTERNATIONAL BUSINESS MACHINES CORPORATION, ARMONK, NY (US)

(72) Inventors: David J. Braun, St. Charles, MN (US); Timothy Jennings, Rochester, MN (US); Theron Lee Lewis, Rochester, MN (US); Abdikarim Hussein, Rochester, MN (US); Anjali Kalpesh Kumar, Rochester, MN (US)

(21) Appl. No.: 18/820,349

(22) Filed: Aug. 30, 2024

(51) Int. Cl. H01L 23/40; H05K 1/02; H05K 7/20

(52) U.S. Cl. CPC H01L 23/4006; H05K 1/0203; H05K 7/20418

(57) ABSTRACT

Automated heatsink removal from a Printed Circuit Board Assembly (PCBA) can include detachably affixing a PCBA to a base fixture. Further, automated heatsink removal can include detachably applying a tool which locks on the base fixture while engaging, using a torque mechanism, and a heatsink coupled to a component on the PCBA. The torque mechanism can be activated in response to softening of thermal interface material between the heatsink and the component and an activation temperature for the torque mechanism being met. The activated torque mechanism loosens the heatsink from the component.

### BACKGROUND

The present disclosure relates to heatsink removal from a printed circuit board assembly (PCMA).

In one example in the area of computer hardware, heatsinks are components that transfer heat away from a hot surface, such as a central processing unit (CPU) or graphics processing unit GPU, to the surrounding air. Heat transfer occurs through conduction, where heat is transferred from a hot surface to the cooler heatsink. The size, shape, and material properties of the heatsink play a crucial role in determining its thermodynamic efficiency. In one example, aluminum and copper are common materials used for heatsinks due to their high thermal conductivity. The surface area of the heatsink is a factor in heat transfer. The larger the surface area, the more heat can be dissipated. The temperature difference between the hot surface and the ambient air can drive the heat transfer process. The rate of heat transfer can also be improved by adding fins or other surface features to increase the heatsink's surface area.

Heatsinks can be designed to maintain a low temperature differential between a hot surface and the ambient air to achieve maximum heat transfer.

In one example, a rework of PCB (Printed Circuit Board) card may be needed, including rework of adhesive attached heatsinks. The heatsinks can have a legacy method of being taken off PCBs by other methods. Other methods may require heating up a PCBA to reach a temperature at which adhesive holding the heatsink to the board release enough for the heatsink to lift off the board. In one example, a cleave method involves using mechanical leverage of a wedge to lift off the heatsink by wedging it between the board and heatsink bottom. In another example, a torque method involves using a tool like a wrench to twist off the heatsink once the adhesive is heated enough. Issues with both these methods can include an increased risk of damage to the PCBA.

### SUMMARY

The present disclosure recognizes the shortcomings and problems associated with current techniques for heatsink removal from a Printed Circuit Board Assembly (PCBA).

The present invention provides a solution for automation of heatsink removal from a PCBA while minimizing risk of damage to the board. In one example, the present invention uses a method, system, or apparatus, to integrate a device or tool that interacts with features of a heatsink coupled to a PCB such that once a certain temperature (e.g., adhesive activation temp) is reached, the device or tool applies a uniform torque to slowly twist and causes separation of the TIM (Thermal Interface Material) from a logic device or heatsink where the TIM couples the heatsink to the PCB. The external torque that is applied can be triggered, for example, electrically, or by using memory metals, or phase change materials. Regardless of the approach, operation of the features above minimizes risk of damage to the PCBA and can provide a more uniform operation to heatsink rework.

The present invention as described herein provides approaches to implement a tool that creates a repeatable consistent approach to remove attached heatsinks from PCBAs. In one example, the invention can apply automated torque to gradually twist a heatsink in a controlled manner, resulting in a separation of the thermal interface material (TIM) from the logic device/heatsink where the TIM couples the heatsink to the PCB.

In an aspect according to the present invention, a method for automated heatsink removal from a Printed Circuit Board Assembly (PCBA) includes, detachably affixing a PCBA to a base fixture. The PCBA including a thermal interface material (TIM) positioned between a heatsink and a component attached to the PCBA, and the TIM couples the heatsink to the component. The method includes detachably applying a tool which locks on the base fixture while engaging, using a torque mechanism, the heatsink. The method includes activating the torque mechanism, in response to the TIM being softened and an activation temperature for the torque mechanism being met. The activating of the torque mechanism loosens the heatsink from the TIM and the component.

In a related aspect, the TIM can be softened by the PCBA being heated to a TIM softening temperature.

In a related aspect, the method can further include heating the PCBA to apply heat to the thermal interface material between the heatsink and the PCBA. And the method can further include, in response to a temperature of the TIM reaching the TIM softening temperature, and the temperature meeting the activation temperature for the torque mechanism. The torque mechanism can be released and thereby loosening the heatsink from the TIM and the PCBA.

In a related aspect, the method further includes removing the tool from the base fixture to disengage the torque mechanism of the tool from the heatsink, in response to the PCBA reaching a threshold cooling temperature. And the method further including removing the loosened heatsink from the component.

In a related aspect, the torque mechanism includes memory metal.

In a related aspect, the torque mechanism includes phase change material.

In a related aspect, the torque mechanism is spring loaded.

In a related aspect, the torque mechanism is electrically activated.

In a related aspect, the torque mechanism is manually activated.

In another aspect according to the present invention, an apparatus for automated heatsink removal from a Printed Circuit Board Assembly (PCBA) can include, a tool being lockable on a base fixture while engageable, using a torque mechanism, with a heatsink. The heatsink can be coupled to a component using thermal interface material (TIM) therebetween, and the component affixed to a PCBA. The torque mechanism is activatable in response to the TIM being softened and an activation temperature for the torque mechanism being met, and the activation of the torque mechanism loosens the heatsink from the component and thereby the PCBA.

In a related aspect, the torque mechanism includes memory metal.

In a related aspect, the torque mechanism includes phase change material.

In a related aspect, the torque mechanism is spring loaded.

In a related, the torque mechanism is electrically activated.

In a related aspect, the torque mechanism is manually activated.

In another aspect according to the present invention, a system for automated heatsink removal from a Printed Circuit Board Assembly (PCBA) includes a computer system comprising; a computer processor, a computer-readable storage medium, and program instructions stored on the computer-readable storage medium being executable by the processor, to cause the computer system to perform the following functions. A function to detachably affix a PCBA to a base fixture, where the PCBA includes a thermal interface material (TIM) positioned between a heatsink and a component attached to the PCBA, and the TIM coupling the heatsink to the component. A function to detachably apply a tool which locks on the base fixture while engaging, using a torque mechanism, the heatsink. A function to activate the torque mechanism, in response to the TIM being softened and an activation temperature for the torque mechanism being met, and the activating of the torque mechanism loosening the heatsink from the TIM and the component.

In a related aspect, the TIM being softened includes the PCBA being heated to a TIM softening temperature.

In a related aspect, the system further includes the functions to: heat the PCBA to apply heat to the thermal interface material between the heatsink and the PCBA; and in response to a temperature of the TIM reaching the TIM softening temperature, and the temperature meeting the activation temperature for the torque mechanism, release the torque mechanism thereby loosening the heatsink from the TIM and the PCBA.

In a related aspect, the system further includes the functions to: remove the tool from the base fixture to disengage the torque mechanism of the tool from the heatsink, in response to the PCBA reaching a threshold cooling temperature; and remove the loosened heatsink from the PCBA.

In a related aspect, the torque mechanism can include memory metal.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. The drawings are discussed forthwith below.

FIG. 1 is a side elevational view of a Printed Circuit Board Assembly (PCBA) including a heatsink.

FIG. 2 is a side elevational view of the PCBA including a locking mechanism.

FIG. 3A is a side elevational view of the PCBA including a removal tool.

FIG. 3B is a side elevational view of the PCBA including the removal tool with a partial sectional view of the removal tool along line AA shown in FIG. 3A.

FIG. 3C is a top view of the PCBA showing the removal tool.

FIG. 4 is a side elevational view of the PCBA including the removal tool in an oven.

FIG. 5 is a top view of the PCBA including the removal tool with activated memory metal with locking features/beams.

FIG. 6 is a side elevational view of the PCBA removed from the oven and with the heatsink removed.

FIG. 7A is a side elevational view of a PCBA with a heat sink according to another embodiment of the disclosure.

FIG. 7B is a top view of a locking mechanism which is part of a removal tool shown in FIG. 8A.

FIG. 8A is a side elevational view of the PCBA with a removal tool attached.

FIG. 8B is a side elevational view of the PCBA with the removal tool attached while being heated.

FIG. 9 is a top view of the locking mechanism.

FIG. 10 is a side elevational view of the heatsink being removed from the PCBA.

FIG. 11 is a side elevational view of the heatsink removed from the PCBA.

FIG. 12A is a side elevational view of a heatsink with a removal tool attached according to another embodiment of the disclosure.

FIG. 12B is a detail view of a portion of the removal tool shown in FIG. 12A.

FIG. 12C is a detail view of the portion of the removal tool shown in FIG. 12B with a spring activated.

FIG. 12D is a top view of a locking mechanism activated by the spring shown in FIGS. 12B and 12C.

FIG. 13A is a side elevational view of a heatsink with a lift mechanism attached to a PCBA according to another embodiment of the disclosure.

FIG. 13B is a detail view of a portion of the lift mechanism.

FIG. 13C is a detail view of the portion of the lift mechanism with a spring activated.

FIG. 13D is a side elevational view of the heatsink being removed from the PCBA using the lift mechanism.

FIG. 14A is a top view of a heatsink on a PCBA according to another embodiment of the disclosure.

FIG. 14B is top view of a removal tool coupled to the heatsink.

FIG. 14C is a top view of the removal took and heatsink before activation.

FIG. 14D is a top view of the removal took and heatsink after activation of the removal tool.

FIG. 15A is a side elevational view of a heatsink on a PCBA with a removal tool attached according to another embodiment of the disclosure.

FIG. 15B is a detail view of a torque mechanism of the removal tool shown in FIG. 15A.

FIG. 15C is a detail view of the torque mechanism once activated.

FIG. 15D is a top view of the torque mechanism rotating.

FIG. 16 is a flow chart according to an embodiment of the disclosure for automatically detaching a heatsink from a PCBA.

FIG. 17 is a schematic block diagram depicting a computer system according to an embodiment of the disclosure, which includes cloud computing components and functions, and which can cooperate with the systems and methods shown in the figures and described herein.

### DETAILED DESCRIPTION

The following description with reference to the accompanying drawings is provided to assist in a comprehensive understanding of exemplary embodiments of the invention as defined by the claims and their equivalents. The description includes various specific details to assist in that understanding, but these are to be regarded as merely exemplary, and assist in providing clarity and conciseness. Accordingly, those of ordinary skill in the art will recognize that various changes and modifications of the embodiments described herein can be made without departing from the scope and spirit of the invention. In addition, descriptions of well-known functions and constructions may be omitted.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

### Embodiments and Examples

Embodiments and figures of the present disclosure may have the same or similar components as other embodiments. Such figures and descriptions illustrate and explain further examples and embodiments according to the present disclosure. Embodiments of the present disclosure can include operational actions and/or procedures. A method, such as a computer-implemented method, can include a series of operational blocks for implementing an embodiment according to the present disclosure which can include cooperation with one or more systems shown in the figures. The operational blocks of the methods and systems according to the present disclosure can include techniques, mechanism, modules, and the like for implementing the functions of the operations in accordance with the present disclosure. Similar components may have the same reference numerals. Components can operate in concert with a computer implemented method. It is understood that a user can be a customer, an individual, or a group of individuals, or a company or an organization.

In one example, embodiments of the present disclosure can include a heatsink PCBA stack-up and a trigger-based torquing mechanism that repeatably and consistently applies a torque at a specific temperature with minimal human influences. Rework can be done at an elevated temperature/in situ as opposed to after the PCBA is taken out of an oven. A trigger mechanism can include, for example, a memory metal (e.g., Nitinol type alloy), a Phase-Change Material, an electrical initiation, or a manual initiation. A trigger can be based on the temperature when an adhesive begins soften. A special fixturing can be used that locks the PCBA with a chip in place, and then a torque mechanism uses leverage to torque the heatsink when at an elevated temperature. An apparatus (which can include: fixturing, torquing mechanism, PCBA, and heatsink stack up) is placed in an oven that provides uniform heating.

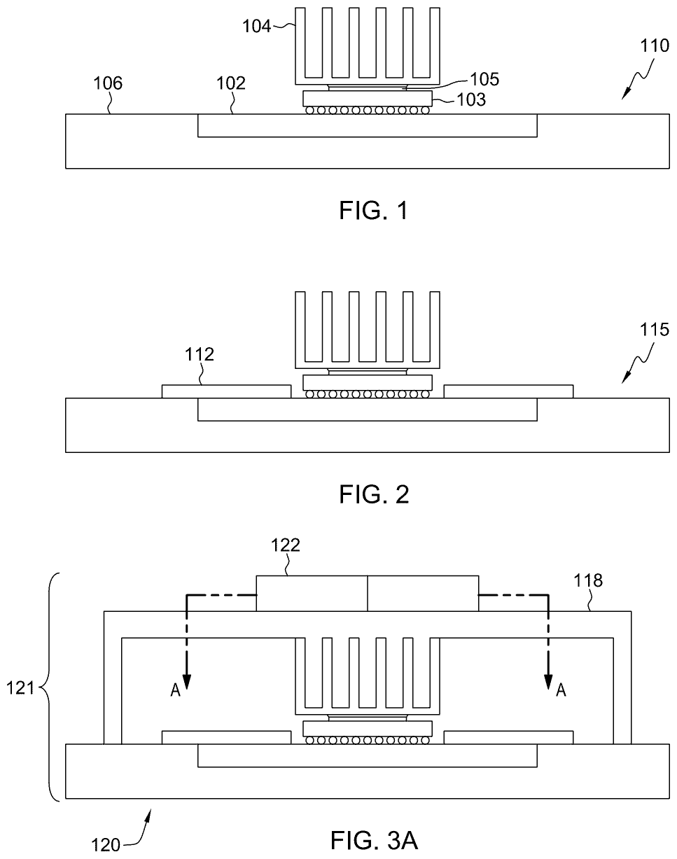

Referring to FIGS. 1, 2 and 3A, 3B, 3C, 4, 5 and 6, in one embodiment according to the present disclosure, a method for automated heatsink removal from a Printed Circuit Board Assembly (PCBA) with use of a memory metal includes, receiving a PCBA 102 which needs a heatsink 104 removed, as shown in FIG. 1. The heatsink is situated over a chip 103 or integrated circuit. Thermal interface material (TIM) 105 is between the chip and the heatsink. Referring to FIG. 1, the method includes placing the PCBA 102 with the attached heatsink 104 in a base fixture 106, as shown in operation 110.

Referring to FIG. 2, the method includes attaching a top fixture and/or top surface locking mechanism 112 to the base fixture 106 and over the PCBA 102. The method includes locking the PCBA 102 into the base fixture 106 with the top surface locking mechanism 112, as in operation 115.

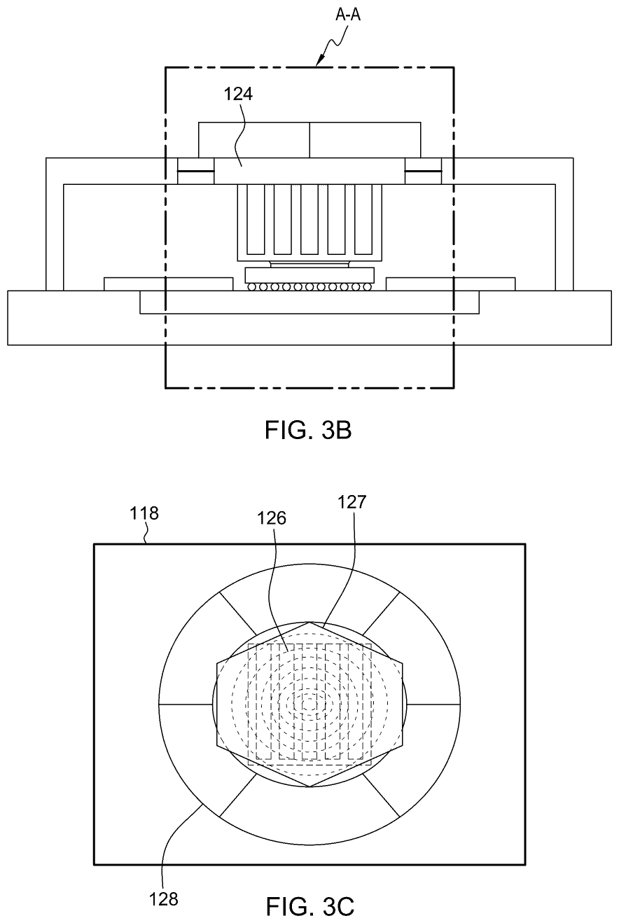

The method includes installing a removal tool apparatus 118 for removal of the heatsink. Referring to FIG. 3A, the removal tool apparatus includes a locking mechanism (not shown) that locks into the base fixture 106, as shown in operation 120. The locking mechanism also includes features 122 that engage the heatsink 104 or the heatsink structure. As shown in FIG. 3B, the features 122 include a locking bar 124. The assembled PCBA, base fixture, heatsink, and removal tool apparatus forms a PCBA and removal tool assembly 121.

Referring to FIGS. 3B and 3C, the heatsink engagement features, include a handle 127 attached to a spring loaded torque mechanism 126 and includes a memory metal locking features/beams 128. The spring loaded torque mechanism 126 is locked in place by the memory metal locking features/beams 128. On top of the spring loaded torque mechanism is the handle 127 as shown in FIG. 3C.

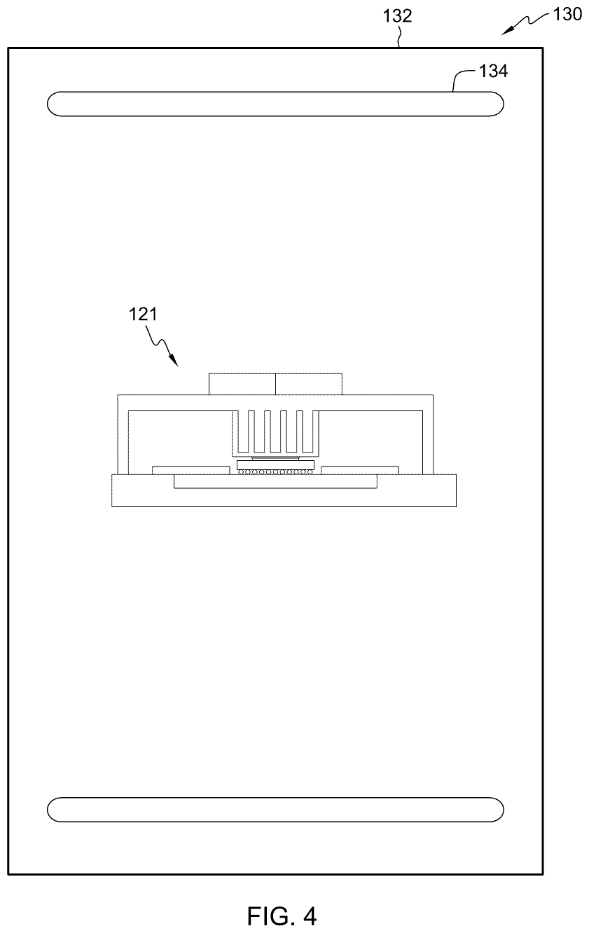

Referring to FIG. 4, the PCBA and removal tool assembly 121 is placed in an oven 132 and allow it to heat up using heating elements 134, as in operation 130. The assembly 121 can reach a high enough temperature that the Thermal Interface Material (TIM) will soften. The memory metal's (e.g., Nitinol type alloy) phase change temperature can be slightly higher than the TIM soften temperature.

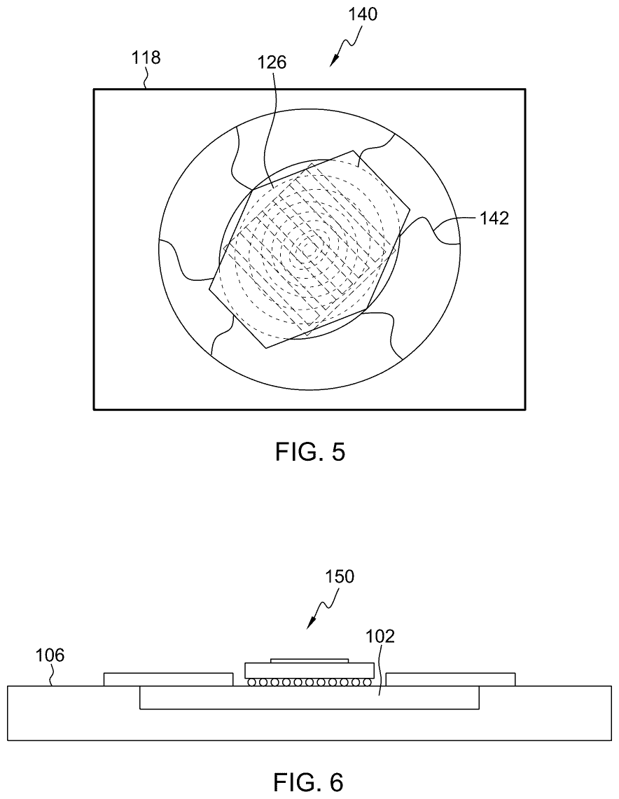

Referring to FIG. 5, when the appropriate temperature is reached, the memory metal locking features change or are activated 142 or change to an activated state, and release the spring loaded torque mechanism 126, which applies shear force to the heatsink causing it to become loose from the TIM and the corresponding PCB of the PCBA, or BGA(Ball Grid Array)/Chip device, as in operation 140. In other words, when the assembly 121 reaches a temperature, the memory metal reacts and releases the torqued spring of the torque mechanism 126. Thereby, the removal tool apparatus 118 torques the heatsink loose while the TIM is in a soften state.

Referring to FIG. 6, the assembly 121 is removed from the oven and allowed to cool. Once cooled, the heatsink removal tool apparatus 118 and the heatsink 104 are removed, as in operation 150. Also, the legacy TIM material can be removed. The BGA/Device is ready for rework which can include a new heatsink. The spring loaded torque mechanism is rotated back to an initial state from an activated state, and memory metal locking features/beams are locked back into an initial position. In other words, the assembly 121 is removed from the oven. The removal tool apparatus is removed, and the loosened heatsink is removed, and the remaining TIM can be cleaned. Thus, the BGA is ready for rework and/or a new heatsink.

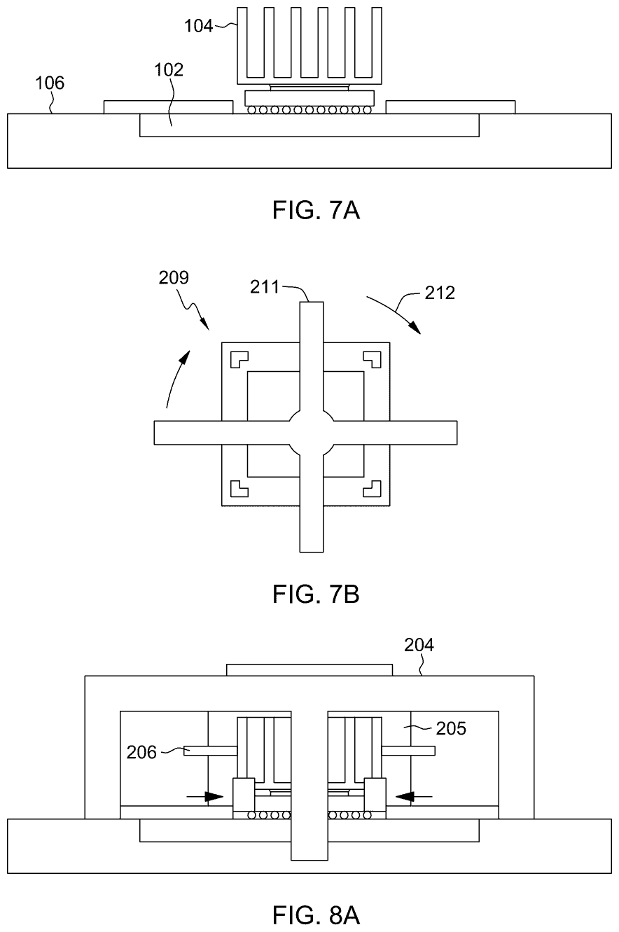

Referring to FIGS. 7A, 7B, 8A, 8B, 9, 10, 11, in one embodiment according to the present disclosure, automated heatsink removal from a Printed Circuit Board Assembly (PCBA) with use of a phase change material includes, receiving a PCBA 102 which needs a heatsink 104 removed, and the PCBA is placed into a base fixture 106, as shown in FIG. 7A.

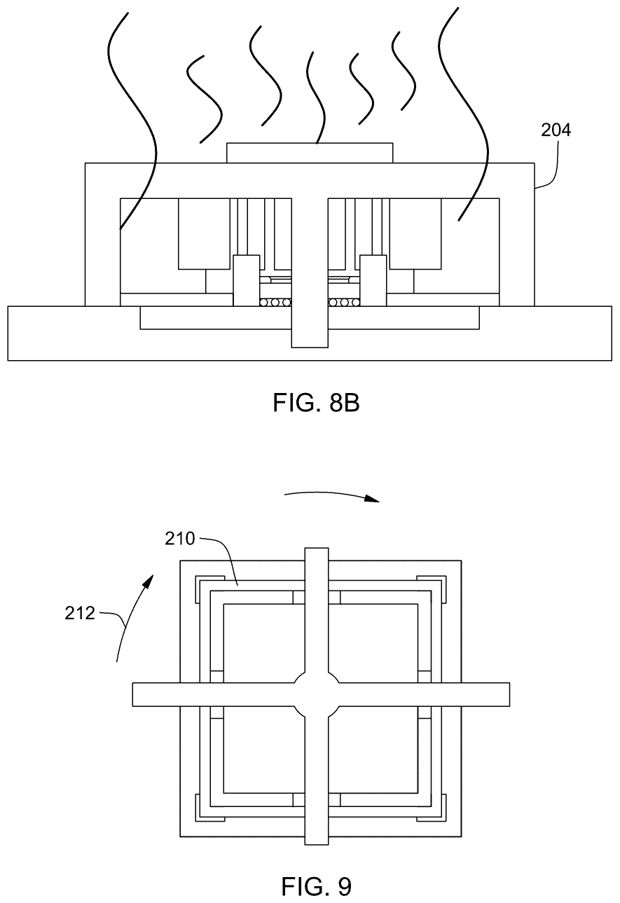

The PCBA is locked into the base fixture with a torque locking mechanism 209, as shown in FIG. 8A, which is part of a heatsink removal apparatus 204 (FIG. 8A). The locking mechanism 209 has a heatsink twist and lift feature 211 (see FIG. 7B) including a spring loaded torque mechanism 210 (FIG. 9).

Referring to FIG. 8A, side buttons 206 can be pressed to lock a mechanism to an underside of the heatsink. The heatsink removal apparatus 204 includes the locking mechanism that locks into the base fixture, and includes features 205 that only engage the heatsink structure. Specifically, the side buttons 206 lock the apparatus 204 to the underside of the heatsink. Also, the side button features can be engaged by a user. The spring loaded torque mechanism 210 can be locked in place by (phase change material) PCM (e.g., phase change temp at 162 degree C.) and the locking mechanism 209 is locked in place by PCM (e.g., phase change temp at 191 degree C.).

The heatsink 104, PCBA 102, and Twist and Lift Feature 211 of the heatsink removal apparatus 204 can be placed in an oven to reach adhesive phase change (solid to liquid) temperature, as shown in FIG. 8B. Once target temp is reached, the PCBA with the Twist and Lift Feature can be extracted. Torsion springs will be released due to PCM reaching temps of 104 deg C. This will create a twisting that will apply uniform torque 212 to the twisting arms in order to release the adhesive or TIM.

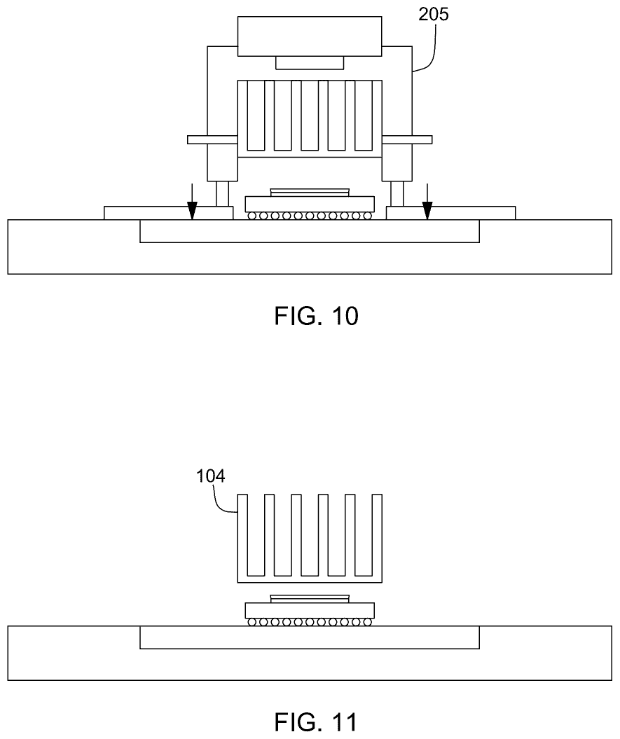

The apparatus should reach a high enough temperature that the Thermal Interface Material (TIM) 105 will soften. The phase change material temperature should be slightly higher than the TIM soften temperature. When the appropriate temperature is reached, the phase change material activates a uniform torque 212 that is applied to the heatsink causing it to become loose from the TIM and the corresponding BGA/Chip device, as shown in FIG. 10. A different higher temp PCM lifting mechanism can be utilized to lift up the heatsink from the TIM and BGA/Chip device along with the features 205, as shown in FIG. 10. For example, an operation can include lifting off twisting arms and pressing button to activate lifting mechanism to lift off the heatsink. The side-buttons can be pressed in once again to release the locking mechanism, to complete the heatsink detachment operation.

Subsequently, the apparatus and PCBA are removed from the oven and allowed to cool. Once cooled, the heatsink removal tool apparatus and the heatsink are removed, as shown in FIG. 11, and the PCBA can be removed from the base. Also, the legacy TIM material can be removed. The BGA/Device is now ready for rework or a new heatsink. The spring loaded torque mechanism is rotated back to initial state and memory metal beams are locked back into an initial position.

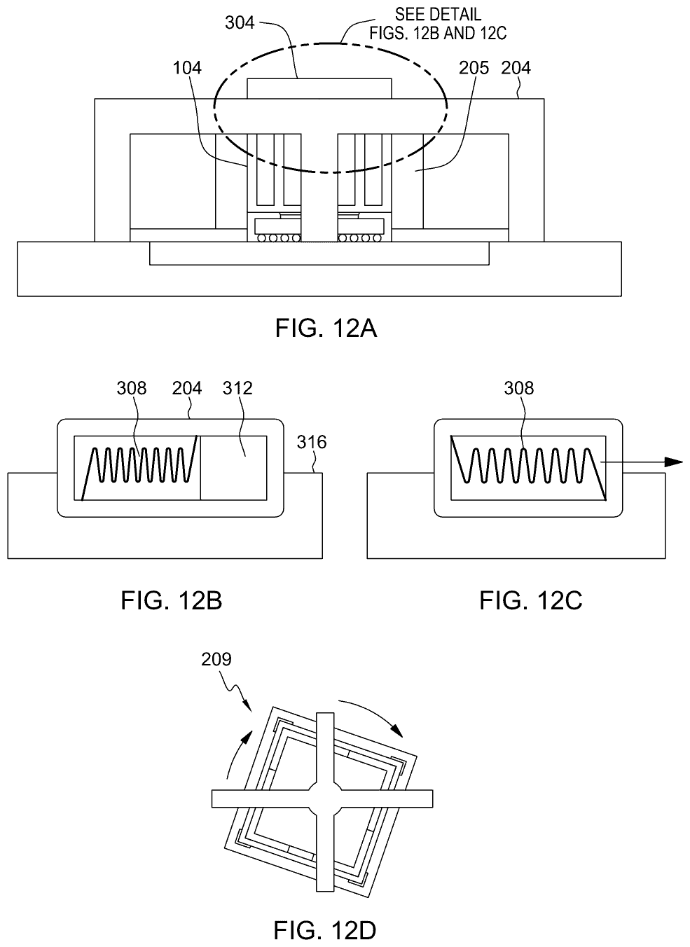

More specifically, referring to FIGS. 12A, 12B, 12C, 12D, an example of a torque locking mechanism 209 is shown which can be used with the phase change material technique described above. Referring to FIG. 12A, the heatsink 104 is shown with the heatsink removal apparatus 204 attached. The heatsink removal apparatus 204 includes a portion 304 which is shown in detail in FIGS. 12B and 12C, and is coupled to a feature 316 of the heatsink removal apparatus. A spring 308 is preloaded for torsion and placed with phase change material (PCM) 312 in a circular track to keep from twisting the heatsink and PCBA before an adhesive melt temperature is reached, as shown in FIG. 12B. The phase change material melts at a specific temperature, e.g., 162 degrees Celsius, and as shown in FIG. 12C, the spring is free to extend when the PCM is heated to its melting point. Referring to FIG. 12D, the freeing of the torsion spring creates a force which twists following tracks and releases the PCBA from the heatsink.

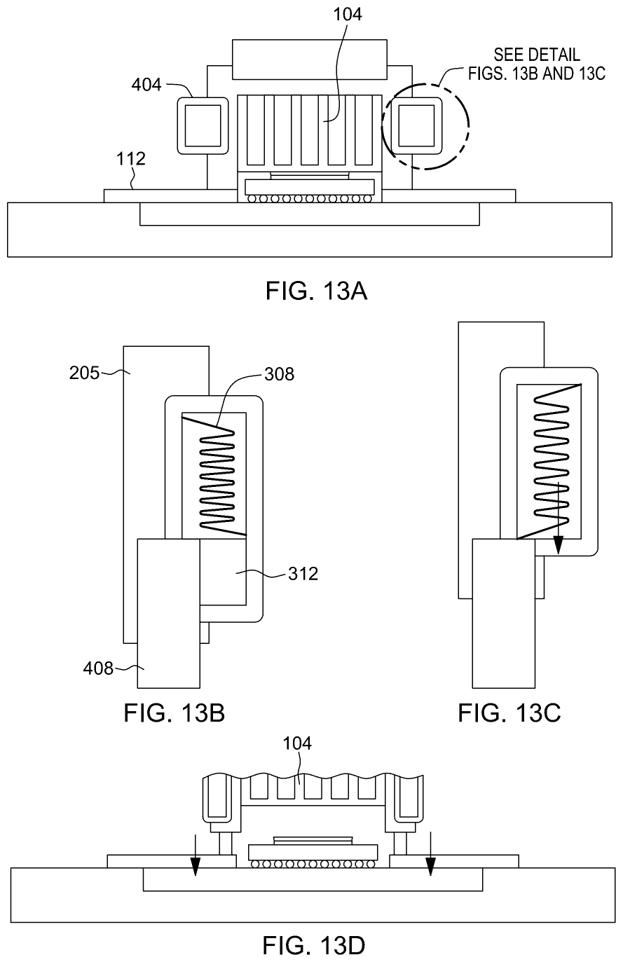

More specifically, referring to FIGS. 13A, 13B, 13C, and 13D, an example of a lift apparatus 404 which includes a lift mechanism 408 is shown which can be used with the phase change material technique described above. Referring to FIG. 13B, a spring 308 is preloaded for compression and placed with PCM 312 to keep from lifting the heatsink 104 before the heatsink and PCBA are fully twisted. Referring to FIG. 13C, once the PCM is melted, the spring pushes the lift mechanism 408 down, for example, to engage a surface, for example, the top surface locking mechanism 112, to lift the heatsink off of the PCBA, as shown in FIG. 13D.

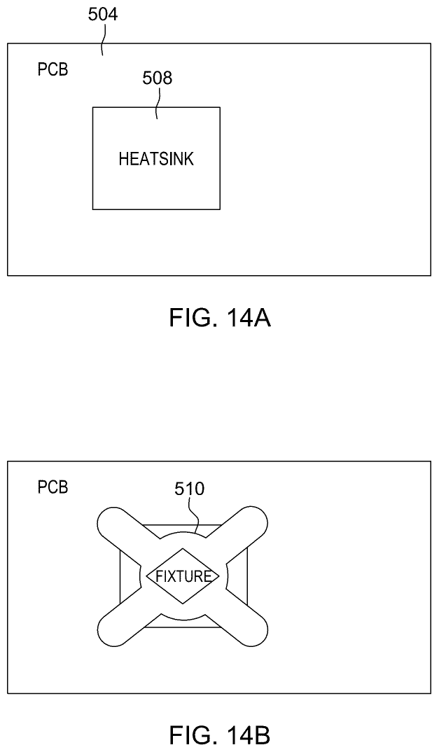

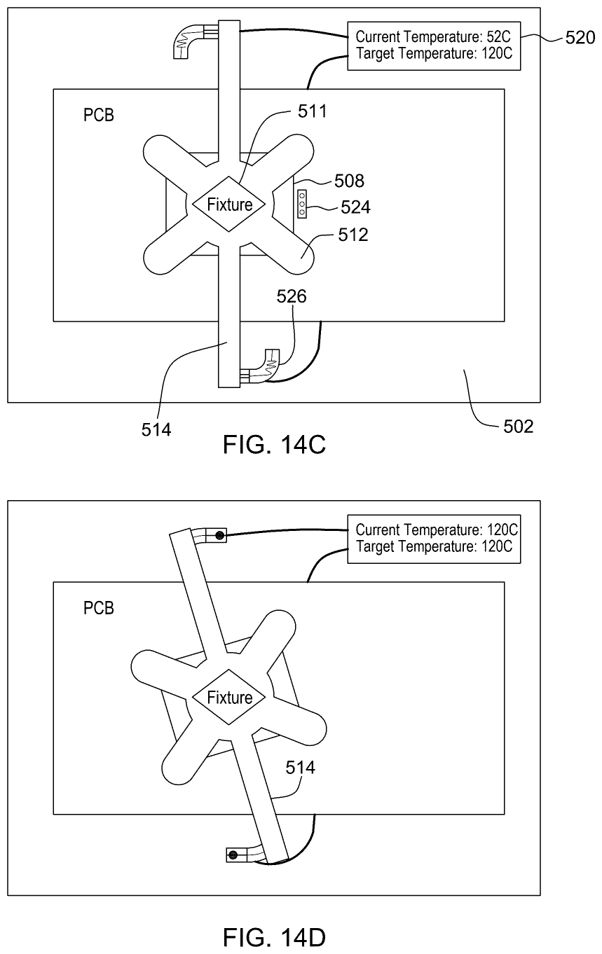

Referring to FIGS. 14, 14A, 14B, 14C, 14D, 15, 16, and 17, in another embodiment of the present disclosure, an electrical trigger can be used for automated heatsink removal from a PCBA. Referring to FIG. 14A, a PCBA 504 with a heatsink 508 for removal is positioned in a base fixture 502, as shown in FIG. 14C. The PCBA is locked into the base fixture 502 with a top surface locking mechanism. A spring force appropriate for the heatsink torque requirements for removal of the heatsink can be determined and set for a fixture trigger.

A removal tool fixture 510 is installed by placing a top cover which adjustably locks into the heatsink with a fixture 511, and the diamond shaped fixture 511 connects to the lever arms 512 which are used to torque the heatsink 508 once an optimum temperature is reached. In one example, a temperature is set by an operator, and once the temperature is reached, as detected by a thermocouple 524, an electrical trigger 520 with a set temperature is initiated, and a loaded spring is released and extended arms 514 move counterclockwise in tracks 526, as shown in FIG. 14D.

For example, the PCBA and apparatus can be placed in an oven and allow it to heat up. When the set temperature is reached (e.g., set by an operator), a spring-loaded torque mechanism is automatically released via electrical trigger 520, and the lever arms 512 with the fixture 511 apply shear force to the heatsink 508 as the extended arms 514 move or rotate in tracks 526, causing the heatsink to become loose from a TIM and the corresponding BGA/Chip device, as in FIG. 14D.

The apparatus and PCBA can then be removed from the oven and allowed to cool. Once cooled, the heatsink removal tool apparatus and the heatsink are removed. Also, the legacy TIM material can be removed, and the BGA/Device is ready for rework or a new heatsink.

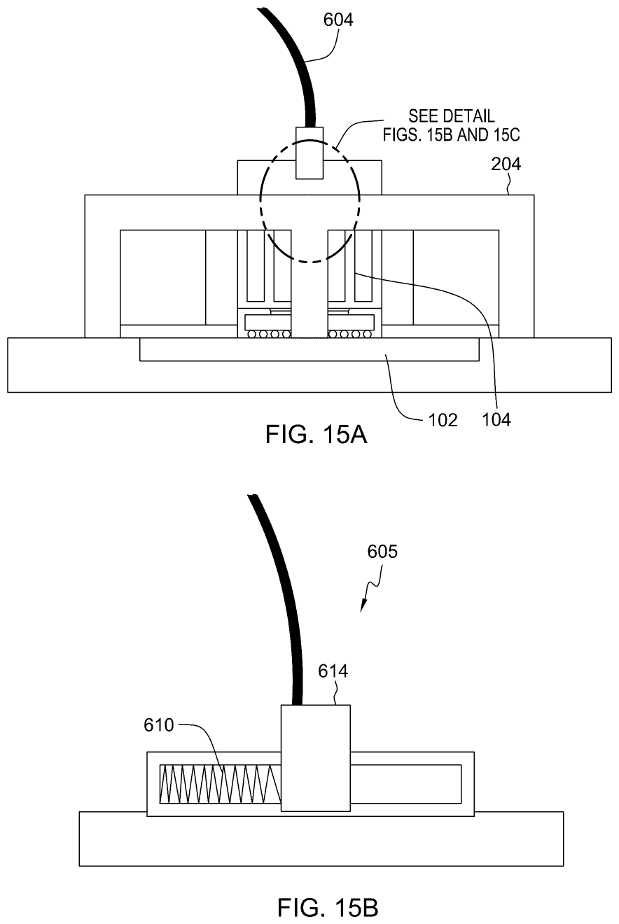

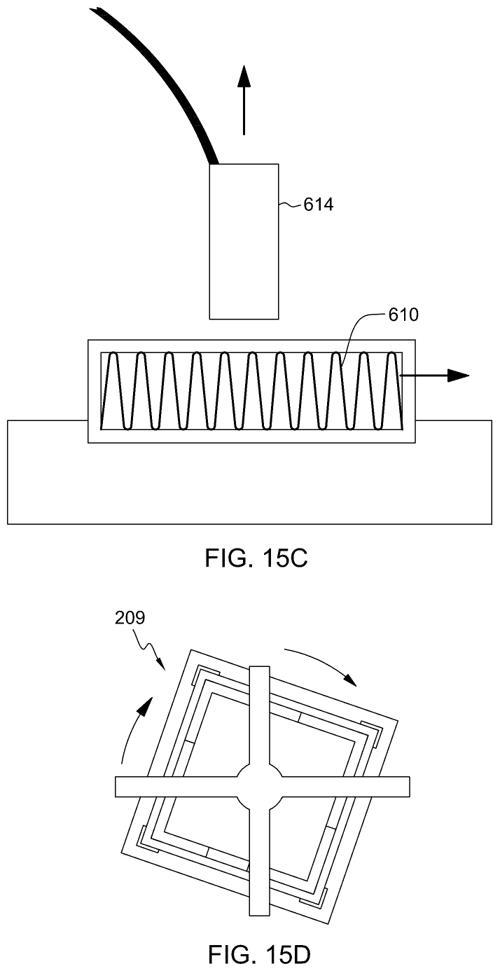

Referring to FIGS. 15A, 15B, 15C, and 15D according to another embodiment of the present disclosure, a manual trigger can be used for automated heatsink removal from a PCBA. Initiation of an automated process to remove the heatsink can be accomplished manually by placing the PCBA 102, including an attached heatsink 104, into a heatsink removal tool apparatus 204. The heatsink removal tool apparatus can include a mechanism that locks the PCBA into a base fixture, a spring-loaded torque mechanism 605 with features that engage the heatsink structure, and a pin 614 which locks the torsion spring 610 in place, as shown in FIG. 15B.

The PCBA can be heated and the removal apparatus can be placed in an oven. The heatsink can be heated for a specified amount of time until a desired temperature is reached at the heatsink interface. The pin 614 can be removed, using the tether 604, when the desired temperature is reached, unlocking the torque mechanism, that is, unlocking the torsion spring 610 so it can apply a shear force to the heatsink, as in FIG. 15C, twisting the heatsink and releasing it from the PCBA and thermal interface material, as shown in FIG. 15D. The torsion spring can be preloaded in a circular track and locked into place with the mechanical pin 614. The tether 604 can be, for example, a chain/string attached to the pin, dislodging the pin and unlocking the spring when the tether is pulled. In another example, a trigger can be pressed that causes the pin to retract. Once the heatsink is dislodged, the PCBA and the apparatus can be removed from the oven, and the PCBA and the apparatus is allowed to cool. Once cooled, the PCBA can be removed from the apparatus.

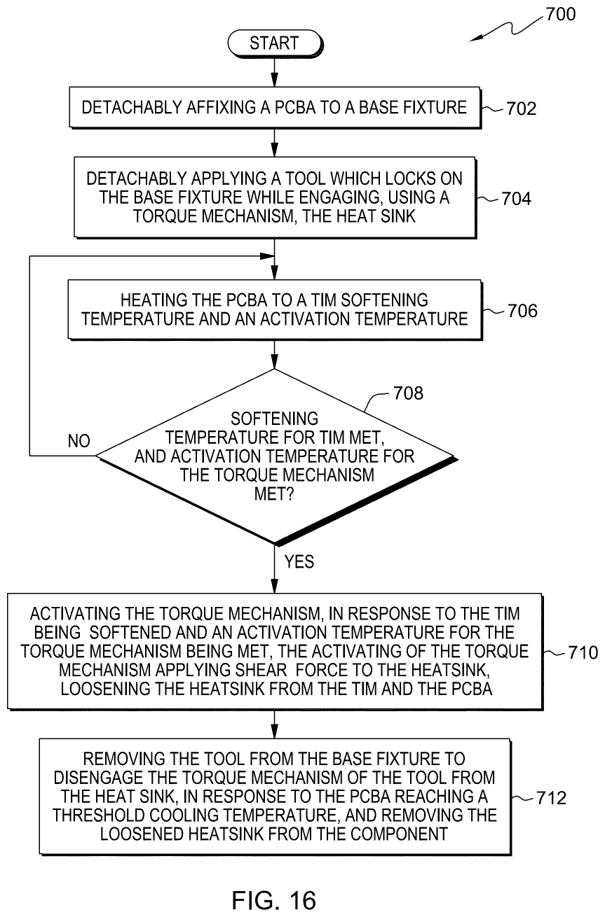

Referring to FIG. 16, in another embodiment of the present disclosure, a method 700 for automated heatsink removal from a PCBA, with reference to example embodiments herein, can include detachably affixing a PCBA 102 to a base fixture 106, as in operation 702, and, for example, with reference to FIGS. 1, 2 and 3. The PCBA 102 includes a thermal interface material 105 (TIM) being positioned between a heatsink 104 and a component, for example, a chip 103, attached to the PCBA 102. The TIM couples the heatsink to the component, and thereby couples the heatsink to the PCBA via the component.

The method includes detachably applying a tool, such as removal tool apparatus 118, which locks on the base fixture while engaging, using a torque mechanism, such as spring loaded torque mechanism 126, the heatsink 104, as in operation 704.

The method includes heating the PCBA to a TIM softening temperature and an activation temperature, as in operation 706, for example, heating in an oven.

Referring to operation 708, when the softening temperature for the TIM is not met, and the activation temperature for the torque mechanism is not met, the method can return to operation 706. When the softening temperature for the TIM is met, and the activation temperature for the torque mechanism is met, the method can proceed to operation 710.

The method includes activating the torque mechanism, in response to the TIM being softened and an activation temperature for the torque mechanism being met, as in operation 710. For example, the torque mechanism being activated in response to the PCBA being heated in an oven to a TIM softening temperature when the PCBA with the heatsink and TIM and the removal tool apparatus and torque mechanism all as a unit are heated in the oven, for example, the oven 132 shown in FIG. 4. In response to the TIM being softened and the activation temperature for the torque mechanism being met, the method can include activating the toque mechanism, as in operation 710, which can include a biased spring. The activating of the torque mechanism applying shear force to the heatsink loosening the heatsink from the TIM and the component and thereby the PCBA, as in operation 710.

The torque mechanism can include, for example, spring activated or biased devices, phase change materials, memory metals, or an electronically activated mechanism. Additionally, measurement for determining the activation temperature for the torque mechanism can include, for example, a thermometer in the oven or a thermocouple device, which upon determination of the activation temperature, initiates or causes the initiation or triggering of the torque mechanism.

Thus, the method can include heating the PCBA to apply heat to the thermal interface material between the heatsink and the PCBA, and in response to a temperature of the TIM reaching the TIM softening temperature, and the temperature meeting the activation temperature for the torque mechanism, the torque mechanism being released and thereby loosening the heatsink from the TIM and the PCBA.

The method can further include removing the tool from the base fixture to disengage the torque mechanism of the tool from the heatsink, in response to the PCBA reaching a threshold cooling temperature, and removing the loosened heatsink from the component, as in operation 712.

In one example, the torque mechanism can include memory metal. In another example, the torque mechanism can include phase change material. In another example, the torque mechanism can be spring loaded. In another example, the torque mechanism can be electrically activated. In another example, the torque mechanism can be manually activated.

In another embodiment according to the present disclosure, an apparatus for automated heatsink removal from a Printed Circuit Board Assembly (PCBA) can include a tool which is lockable on a base fixture while engageable, using a torque mechanism, with a heatsink. For example, referring to FIGS. 1, 2 and 3A, the tool 118 is lockable on the base fixture 106 while engageable, using the torque mechanism 126, with the heatsink 104. The heatsink is affixed to a PCBA 102 using thermal interface material (TIM) 105 therebetween. The torque mechanism is activatable in response to the TIM being softened and an activation temperature for the torque mechanism being met. The activation of the torque mechanism applies shear force to the heatsink which loosens the heatsink from the TIM and the PCBA.

In another embodiment according to the present disclosure, a system for automated heatsink removal from a Printed Circuit Board Assembly (PCBA) can include a computer system comprising; a computer processor, a computer-readable storage medium, and program instructions stored on the computer-readable storage medium being executable by the processor, to cause the computer system to perform the following functions. A function to detachably affix a PCBA to a base fixture, where the PCBA includes a thermal interface material (TIM) positioned between a heatsink connected to the PCBA. The PCBA and the TIM affixing the heatsink to the PCBA. The system includes another function to detachably apply a tool which locks on the base fixture while engaging, using a torque mechanism, the heatsink. The apparatus includes another function to activate the torque mechanism, in response to the TIM being softened and an activation temperature for the torque mechanism being met, which can include the PCBA being heated to a TIM softening temperature. The function to activate the torque mechanism can include the activation of the torque mechanism applying shear force to the heatsink which loosens the heatsink from the TIM and the PCBA.

In another embodiment according to the present disclosure, a computer program product for automated heatsink removal from a Printed Circuit Board Assembly (PCBA). The computer program product can include a computer readable storage medium having program instructions embodied therewith, and the program instructions are executable by a computer to cause the computer to perform functions as follows. A function to detachably affix a PCBA to a base fixture. The PCBA can include a thermal interface material (TIM) positioned between a heatsink connected to the PCBA and the PCBA. The TIM affixes the heatsink to the PCBA.

Another function can detachably apply a tool which locks on the base fixture while engaging, using a torque mechanism, the heatsink. Another function can activate the torque mechanism, in response to the TIM being softened and an activation temperature for the torque mechanism being met. In response to the PCBA being heated to a TIM softening temperature, activation of the torque mechanism applies shear force to the heatsink loosening the heatsink from the TIM and the PCBA.

In one embodiment according to the present disclosure, a method and/or a system for automated heatsink removal from a Printed Circuit Board Assembly (PCBA) can include detachably affixing a PCBA to a base fixture. The PCBA includes a thermal interface material (TIM) being positioned between a heatsink and a connector connected to the PCBA. A tool is installed which locks on the base fixture while engaging the heatsink with a torque mechanism. The TIM is softened in response to the PCBA being heated to a TIM softening temperature, the torque mechanism releases thereby applying shear force to the heatsink loosening the heatsink from the TIM and the component and thereby the PCBA. The PCBA can be heated to apply heat to the thermal interface material between the heatsink and the component. In response to a temperature of the TIM reaching the TIM softening temperature, the torque mechanism is released and thereby loosens the heatsink from the TIM and the component. The method and/or system includes removing the tool from the base fixture to disengage the tool from the heatsink, when the PCBA reaches a threshold cooling temperature, and removing the loosened heatsink from the PCBA. Embodiments of the present disclosure thereby include providing a torque mechanism which is automatic as being initiated by a threshold temperature to remove the heatsink from a component and the PCBA.

### Other Examples and Embodiments

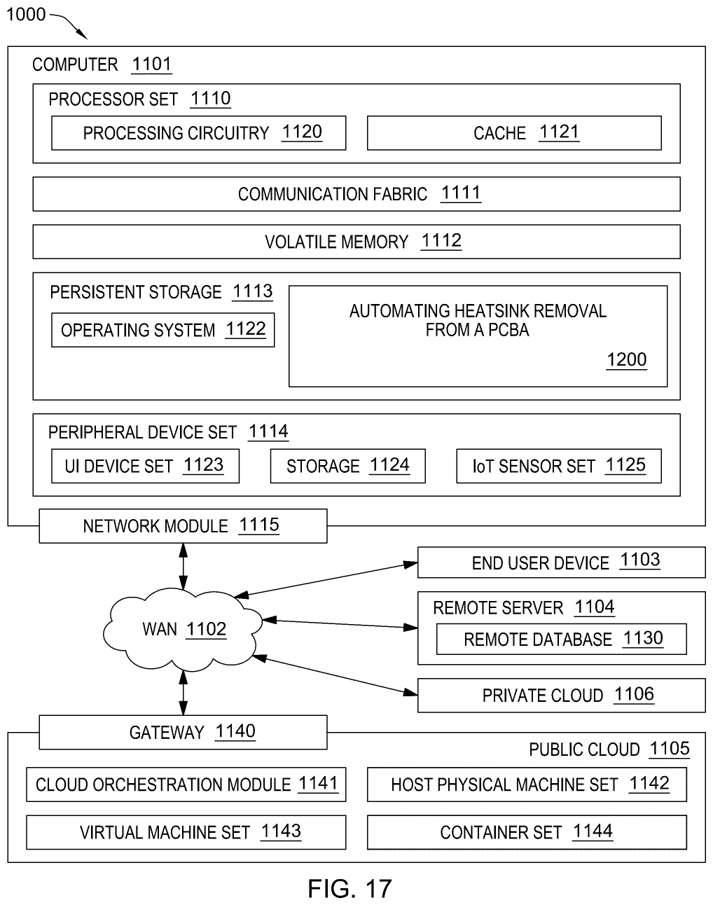

In another example, a computer which can be part of a device can initiate sending an electrical signal to initiate a torque mechanism. The computer can include a processor and a computer readable storage medium where an software application can be stored which can in one example, embody all or part of the method of the present disclosure. The application can include all or part of instructions to implement the method of the present disclosure, embodied in code and stored on a computer readable storage medium. In one example, a device can include a display. The computer and/or the device can operate, in all or in part, in conjunction with a remote server by way of a communications network, for example, the Internet. In one example, the electrical trigger 520, shown in FIG. 14C can be initiated by a computer, such as the computer 1101 shown in FIG. 17.

Also, referring to the figures, a device can include a computer, computer readable storage medium, and operating systems, and/or programs, and/or a software application, which can include program instructions executable using a processor. Embodiments of these features are shown herein in the figures. The method according to the present disclosure, can include a computer for implementing the features of the method, according to the present disclosure, as part of a control system. In another example, a computer as part of a control system can work in corporation with a mobile device computer in concert with communication system for implementing the features of the method according to the present disclosure. In another example, a computer for implementing the features of the method can be part of a mobile device and thus implement the method locally.

In one example, a system according to the present disclosure can include a control system communicating with a user device via a communications network. The control system can incorporate all or part of an application or software for implementing the method of the present disclosure. The control system can include a computer readable storage medium where account data and/or registration data can be stored. User profiles can be part of the account data and stored on the storage medium. The control system can include a computer having computer readable storage medium and software programs stored therein. A processor can be used to execute or implement the instructions of the software program. The control system can also include a database.

In another example and embodiment, profiles can be saved for entities such as users, participants, operators, human operators, or robotic devices. Such profiles can supply data regarding the user and history of deliveries for analysis. In one example, a user can register or create an account using the control system which can include one or more profiles as part of registration and/or account data. The registration can include profiles for each user having personalized data. For example, users can register using a website via their computer and GUI (Graphical User Interface) interface. The registration or account data can include profiles for an account for each user. Such accounts can be stored on the control system, which can also use the database for data storage. A user and a related account can refer to, for example, a person, an administrator, or an operator, or an entity, or a corporate entity, or a corporate department, or another machine such as an entity for automation such as a system using, in all or in part, artificial intelligence.

Account data, for instance, including profile data related to a user, and any data, personal or otherwise, can be collected and stored, for example, in a control system. It is understood that such data collection is done with the knowledge and consent of a user, and stored to preserve privacy, including deletion of data and accounts.

### Other Additional Embodiments and Examples

In one example, Artificial Intelligence (AI) can be used, all or in part, for generating a model or a learning model as discussed herein in embodiments of the present disclosure. An Artificial Intelligence (AI) System can include machines, computer, and computer programs which are designed to be intelligent or mirror intelligence. Such systems can include computers executing algorithms. AI can include machine learning and deep learning. For example, deep learning can include neural networks. An AI system can be cloud based, that is, using a cloud-based computing environment having computing resources. In another example, a control system can be all or part of an Artificial Intelligence (AI) system. For example, the control system can be one or more components of an AI system

### More Examples and Embodiments

Additionally, methods and systems according to embodiments of the present disclosure can be discussed in relation to a functional system(s) depicted by functional block diagrams. The methods and systems can include components and operations for embodiments according to the present disclosure, and is used herein for reference when describing the operational steps of the methods and systems of the present disclosure. Additionally, the functional system, according to an embodiment of the present disclosure, depicts functional operations indicative of the embodiments discussed herein.

The methods and systems of the present disclosure can include a series of operational blocks for implementing one or more embodiments according to the present disclosure. A method shown in the figures may be another example embodiment, which can include aspects/operations shown in another figure and discussed previously, but can be reintroduced in another example. Thus, operational blocks and system components shown in one or more of the figures may be similar to operational blocks and system components in other figures. The diversity of operational blocks and system components depict example embodiments and aspects according to the present disclosure. For example, methods shown are intended as example embodiments which can include aspects/operations shown and discussed previously in the present disclosure, and in one example, continuing from a previous method shown in another flow chart.

It is understood that the features shown in some of the figures, for example block diagrams, are functional representations of features of the present disclosure. Such features are shown in embodiments of the systems and methods of the present disclosure for illustrative purposes to clarify the functionality of features of the present disclosure.

The descriptions of the various embodiments of the present invention have been presented for purposes of illustration, but are not intended to be exhaustive or limited to the embodiments disclosed. Likewise, examples of features or functionality of the embodiments of the disclosure described herein, whether used in the description of a particular embodiment, or listed as examples, are not intended to limit the embodiments of the disclosure described herein, or limit the disclosure to the examples described herein. Such examples are intended to be examples or exemplary, and non-exhaustive. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is also understood that the one or more computers or computer systems shown in the figures can include all or part of a computing environment and its components shown in another figure, for example, the computing environment 1000 can be incorporated, in all or in part, in one or more computers or devices shown in other figures and described herein. In one example, the one or more computers can communicate with all or part of a computing environment and its components as a remote computer system to achieve computer functions described in the present disclosure.

### More Additional Examples and Embodiments

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves opropagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Referring to FIG. 17, a computing environment 1000 contains an example of an environment for the execution of at least some of the computer code involved in performing the inventive methods, such as using a computer for automating heatsink removal from a PCBA 1200. In addition to block 1200, computing environment 1000 includes, for example, computer 1101, wide area network (WAN) 1102, end user device (EUD) 1103, remote server 1104, public cloud 1105, and private cloud 1106. In this embodiment, computer 1101 includes processor set 1110 (including processing circuitry 1120 and cache 1121), communication fabric 1111, volatile memory 1112, persistent storage 1113 (including operating system 1122 and block 1200, as identified above), peripheral device set 1114 (including user interface (UI), device set 1123, storage 1124, and Internet of Things (IoT) sensor set 1125), and network module 1115. Remote server 1104 includes remote database 1130. Public cloud 1105 includes gateway 1140, cloud orchestration module 1141, host physical machine set 1142, virtual machine set 1143, and container set 1144.

COMPUTER 1101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1130. As is well understood in the art of computer technology, and depending upon the technology, performance of a computer-implemented method may be distributed among multiple computers and/or between multiple locations. On the other hand, in this presentation of computing environment 1100, detailed discussion is focused on a single computer, specifically computer 1101, to keep the presentation as simple as possible. Computer 1101 may be located in a cloud, even though it is not shown in a cloud in FIG. 7. On the other hand, computer 1101 is not required to be in a cloud except to any extent as may be affirmatively indicated.

PROCESSOR SET 1110 includes one, or more, computer processors of any type now known or to be developed in the future. Processing circuitry 1120 may be distributed over multiple packages, for example, multiple, coordinated integrated circuit chips. Processing circuitry 1120 may implement multiple processor threads and/or multiple processor cores. Cache 1121 is memory that is located in the processor chip package(s) and is typically used for data or code that should be available for rapid access by the threads or cores running on processor set 1110. Cache memories are typically organized into multiple levels depending upon relative proximity to the processing circuitry. Alternatively, some, or all, of the cache for the processor set may be located “off chip.” In some computing environments, processor set 1110 may be designed for working with qubits and performing quantum computing.

Computer readable program instructions are typically loaded onto computer 1101 to cause a series of operational steps to be performed by processor set 1110 of computer 1101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1121 and the other storage media discussed below. The program instructions, and associated data, are accessed by processor set 1110 to control and direct performance of the inventive methods. In computing environment 1100, at least some of the instructions for performing the inventive methods may be stored in block 1200 in persistent storage 1113.

COMMUNICATION FABRIC 1111 is the signal conduction paths that allow the various components of computer 1101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1112 is any type of volatile memory now known or to be developed in the future. Examples include dynamic type random access memory (RAM) or static type RAM. Typically, the volatile memory is characterized by random access, but this is not required unless affirmatively indicated. In computer 1101, the volatile memory 1112 is located in a single package and is internal to computer 1101, but, alternatively or additionally, the volatile memory may be distributed over multiple packages and/or located externally with respect to computer 1101.

PERSISTENT STORAGE 1113 is any form of non-volatile storage for computers that is now known or to be developed in the future. The non-volatility of this storage means that the stored data is maintained regardless of whether power is being supplied to computer 1101 and/or directly to persistent storage 1113. Persistent storage 1113 may be a read only memory (ROM), but typically at least a portion of the persistent storage allows writing of data, deletion of data and re-writing of data. Some familiar forms of persistent storage include magnetic disks and solid state storage devices. Operating system 1122 may take several forms, such as various known proprietary operating systems or open source Portable Operating System Interface type operating systems that employ a kernel. The code included in block 1200 typically includes at least some of the computer code involved in performing the inventive methods.

PERIPHERAL DEVICE SET 1114 includes the set of peripheral devices of computer 1101. Data communication connections between the peripheral devices and the other components of computer 1101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1123 may include components such as a display screen, speaker, microphone, wearable devices (such as goggles and smart watches), keyboard, mouse, printer, touchpad, game controllers, and haptic devices. Storage 1124 is external storage, such as an external hard drive, or insertable storage, such as an SD card. Storage 1124 may be persistent and/or volatile. In some embodiments, storage 1124 may take the form of a quantum computing storage device for storing data in the form of qubits. In embodiments where computer 1101 is required to have a large amount of storage (for example, where computer 1101 locally stores and manages a large database) then this storage may be provided by peripheral storage devices designed for storing very large amounts of data, such as a storage area network (SAN) that is shared by multiple, geographically distributed computers. IoT sensor set 1125 is made up of sensors that can be used in Internet of Things applications. For example, one sensor may be a thermometer and another sensor may be a motion detector.

NETWORK MODULE 1115 is the collection of computer software, hardware, and firmware that allows computer 1101 to communicate with other computers through WAN 1102. Network module 1115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1115 are performed on the same physical hardware device. In other embodiments (for example, embodiments that utilize software-defined networking (SDN)), the control functions and the forwarding functions of network module 1115 are performed on physically separate devices, such that the control functions manage several different network hardware devices. Computer readable program instructions for performing the inventive methods can typically be downloaded to computer 1101 from an external computer or external storage device through a network adapter card or network interface included in network module 1115.

WAN 1102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1103 is any computer system that is used and controlled by an end user (for example, a customer of an enterprise that operates computer 1101), and may take any of the forms discussed above in connection with computer 1101. EUD 1103 typically receives helpful and useful data from the operations of computer 1101. For example, in a hypothetical case where computer 1101 is designed to provide a recommendation to an end user, this recommendation would typically be communicated from network module 1115 of computer 1101 through WAN 1102 to EUD 1103. In this way, EUD 1103 can display, or otherwise present, the recommendation to an end user. In some embodiments, EUD 1103 may be a client device, such as thin client, heavy client, mainframe computer, desktop computer and so on.

REMOTE SERVER 1104 is any computer system that serves at least some data and/or functionality to computer 1101. Remote server 1104 may be controlled and used by the same entity that operates computer 1101. Remote server 1104 represents the machine(s) that collect and store helpful and useful data for use by other computers, such as computer 1101. For example, in a hypothetical case where computer 1101 is designed and programmed to provide a recommendation based on historical data, then this historical data may be provided to computer 1101 from remote database 1130 of remote server 1104.

PUBLIC CLOUD 1105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1105 is performed by the computer hardware and/or software of cloud orchestration module 1141. The computing resources provided by public cloud 1105 are typically implemented by virtual computing environments that run on various computers making up the computers of host physical machine set 1142, which is the universe of physical computers in and/or available to public cloud 1105. The virtual computing environments (VCEs) typically take the form of virtual machines from virtual machine set 1143 and/or containers from container set 1144. It is understood that these VCEs may be stored as images and may be transferred among and between the various physical machine hosts, either as images or after instantiation of the VCE. Cloud orchestration module 1141 manages the transfer and storage of images, deploys new instantiations of VCEs and manages active instantiations of VCE deployments. Gateway 1140 is the collection of computer software, hardware, and firmware that allows public cloud 1105 to communicate through WAN 1102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1106 is similar to public cloud 1105, except that the computing resources are only available for use by a single enterprise. While private cloud 1106 is depicted as being in communication with WAN 1102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1105 and private cloud 1106 are both part of a larger hybrid cloud.

What is claimed is:

1. A method for automated heatsink removal from a Printed Circuit Board Assembly (PCBA), comprising:
detachably affixing a PCBA to a base fixture, the PCBA including a thermal interface material (TIM) being positioned between a heatsink and a component attached to the PCBA, and the TIM coupling the heatsink to the component;
detachably applying a tool which locks on the base fixture while engaging, using a torque mechanism, the heatsink; and
activating the torque mechanism, in response to the TIM being softened and an activation temperature for the torque mechanism being met, the activating of the torque mechanism loosening the heatsink from the TIM and the component.

2. The method of claim 1, wherein the TIM being softened includes the PCBA being heated to a TIM softening temperature.

3. The method of claim 1, further comprising:
heating the PCBA to apply heat to the thermal interface material between the heatsink and the PCBA; and
in response to a temperature of the TIM reaching the TIM softening temperature, and the temperature meeting the activation temperature for the torque mechanism, the torque mechanism being released and thereby loosening the heatsink from the TIM and the PCBA.

4. The method of claim 3, further comprising:
removing the tool from the base fixture to disengage the torque mechanism of the tool from the heatsink, in response to the PCBA reaching a threshold cooling temperature; and
removing the loosened heatsink from the component.

5. The method of claim 1, wherein the torque mechanism includes memory metal.

6. The method of claim 1, wherein the torque mechanism includes phase change material.

7. The method of claim 1, wherein the torque mechanism is spring loaded.

8. The method of claim 1, wherein the torque mechanism is electrically activated.

9. The method of claim 1, wherein the torque mechanism is manually activated.

10. An apparatus for automated heatsink removal from a Printed Circuit Board Assembly (PCBA), which comprises:
a tool being lockable on a base fixture while engageable, using a torque mechanism, with a heatsink, the heatsink coupled to a component using thermal interface material (TIM) therebetween, and the component affixed to a PCBA, the torque mechanism being activatable in response to the TIM being softened and an activation temperature for the torque mechanism being met, the activation of the torque mechanism loosens the heatsink from the component and thereby the PCBA.

11. The apparatus of claim 10, wherein the torque mechanism includes memory metal.

12. The apparatus of claim 10, wherein the torque mechanism includes phase change material.

13. The apparatus of claim 10, wherein the torque mechanism is spring loaded.

14. The apparatus of claim 10, wherein the torque mechanism is electrically activated.

15. The apparatus of claim 10, wherein the torque mechanism is manually activated.

16. A system for automated heatsink removal from a Printed Circuit Board Assembly (PCBA), which comprises:
a computer system comprising; a computer processor, a computer-readable storage medium, and program instructions stored on the computer-readable storage medium being executable by the processor, to cause the computer system to perform the following functions to;
detachably affix a PCBA to a base fixture, the PCBA including a thermal interface material (TIM) being positioned between a heatsink and a component attached to the PCBA, and the TIM coupling the heatsink to the component;
detachably apply a tool which locks on the base fixture while engaging, using a torque mechanism, the heatsink; and
activate the torque mechanism, in response to the TIM being softened and an activation temperature for the torque mechanism being met, the activating of the torque mechanism loosening the heatsink from the TIM and the component.

17. The system of claim 16, wherein the TIM being softened includes the PCBA being heated to a TIM softening temperature.

18. The system of claim 16, further comprising the functions to:
heat the PCBA to apply heat to the thermal interface material between the heatsink and the PCBA; and
in response to a temperature of the TIM reaching the TIM softening temperature, and the temperature meeting the activation temperature for the torque mechanism, release the torque mechanism thereby loosening the heatsink from the TIM and the PCBA.

19. The system of claim 18, further comprising the functions to:
remove the tool from the base fixture to disengage the torque mechanism of the tool from the heatsink, in response to the PCBA reaching a threshold cooling temperature; and
remove the loosened heatsink from the PCBA.

20. The system of claim 16, wherein the torque mechanism includes memory metal.
